(19) United States
(12) Patent Application Publication
(10) Pub. No.: US 2024/0294794 A1
(43) Pub. Date: Sep. 5, 2024

(54) COPOLYMER, PIEZOELECTRIC MATERIAL, PIEZOELECTRIC FILM AND PIEZOELECTRIC ELEMENT

(71) Applicant: TDK CORPORATION, Tokyo (JP)

(72) Inventor: Junichi HOSHINO, Tokyo (JP)

(73) Assignee: TDK CORPORATION, Tokyo (JP)

(21) Appl. No.: 17/800,491

(22) PCT Filed: Mar. 28, 2022
(86) PCT No.: PCT/JP2022/015022

§ 371 Date: Aug. 17, 2022

(30) Foreign Application Priority Data
Mar. 29, 2021 (JP) 2021-054912

(51) Int. Cl. C09D 133/20; H10N 30/857

(52) U.S. Cl. CPC C09D 133/20; H10N 30/857

(57) ABSTRACT

A copolymer having a structural unit represented by Formula (1) (R¹ and R² represent any one selected from the group consisting of a hydrogen atom, a methyl group, a dimethyl group, an ethyl group, an isopropyl group, an isobutyl group, a phenyl group, and a benzyl group, or R¹ and R² form a benzooxazolidinone framework together with an oxazolidinone ring) and a structural unit represented by Formula (2):

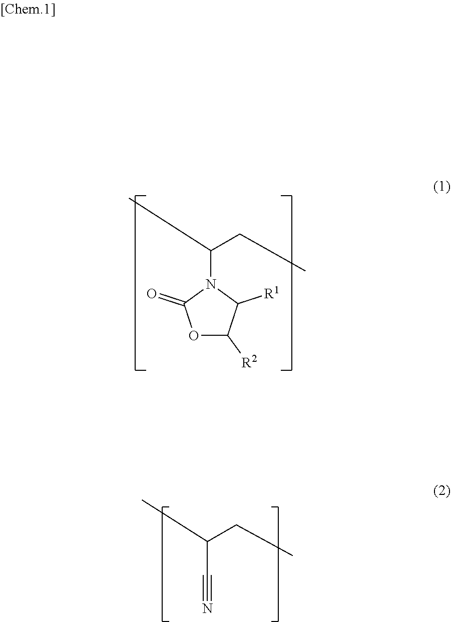

### TECHNICAL FIELD

The present disclosure relates to a copolymer, a piezoelectric material, a piezoelectric film and a piezoelectric element.

Priority is claimed on Japanese Patent Application No. 2021-054912, filed Mar. 29, 2021, the content of which is incorporated herein by reference.

### BACKGROUND ART

In the related art, a ceramic material PZT (PbZrO₃—PbTiO₃-based solid solution) is often used as a piezoelectric material forming a piezoelectric component of a piezoelectric element. However, PZT has a disadvantage that it is brittle because it is a ceramic containing lead. Therefore, as a piezoelectric material, a material having a small load on the environment and high flexibility is required.

As a piezoelectric material that meets such demands, it is conceivable to use a polymer piezoelectric material. Examples of polymer piezoelectric materials include strongly dielectric polymers such as polyvinylidene fluoride (PVDF) and vinylidene fluoride-trifluoroethylene copolymers (P(VDF-TrFE)). However, these strongly dielectric polymers have insufficient heat resistance. Therefore, a conventional piezoelectric component made of a strongly dielectric polymer loses its piezoelectric properties at a high temperature, and its physical properties such as an elastic modulus deteriorate. Accordingly, a piezoelectric element having a conventional piezoelectric component made of a strongly dielectric polymer has a narrow temperature range in which it can be used.

In addition, as a piezoelectric material, there is an amorphous polymer piezoelectric material that acquires piezoelectricity by cooling under polarization at a temperature near the glass transition temperature. Amorphous polymers lose their piezoelectric properties at a temperature near the glass transition temperature. Therefore, there is a demand for an amorphous polymer piezoelectric material having a high glass transition temperature and favorable heat resistance.

Examples of amorphous polymer piezoelectric materials having a high glass transition temperature include vinylidene cyanide-vinyl acetate copolymers (for example, refer to Patent Document 1). However, for vinylidene cyanide-vinyl acetate copolymers, it is necessary to use vinylidene cyanide, which is difficult to handle, as the raw material monomer.

In addition, as raw material monomers for a polymer piezoelectric material, it is conceivable to use acrylonitrile, which is easy to handle, without using vinylidene cyanide. However, a polymer using acrylonitrile as a raw material monomer has a low glass transition temperature. In addition, a polymer using acrylonitrile as a raw material monomer has low piezoelectric properties (for example, refer to Non-Patent Document 1 and Non-Patent Document 2).

### CITATION LIST

### Patent Literature

[Patent Document 1]
PCT International Publication No. WO 1991/013922

### Non-Patent Literature

[Non-Patent Document 1]
H. Ueda, S. Carr, Piezoelectricity in Polyacrylonitrile. Polym J 16, 661-667 (1984).
[Non-Patent Document 2]
H. von Berlepsch, W. Kunstler, Piezoelectricity in acrylonitrile/methylacrylate copolymer. Polymer Bulletin 19, 305-309(1988).

### SUMMARY OF INVENTION

### Technical Problem

Conventionally, there has been a demand for a polymer piezoelectric material from which a piezoelectric film having high heat resistance and piezoelectric properties can be obtained.

The present disclosure has been made in view of the above circumstances, and an object of the present disclosure is to provide a copolymer that can be used as a piezoelectric material from which a piezoelectric film having high heat resistance and piezoelectric properties can be obtained.

In addition, an object of the present disclosure is to provide a piezoelectric material which contains the copolymer of the present disclosure and from which a piezoelectric film having high heat resistance and piezoelectric properties can be obtained.

In addition, an object of the present disclosure is to provide a piezoelectric film containing the piezoelectric material of the present disclosure and having high heat resistance and piezoelectric properties, and a piezoelectric element including the piezoelectric film of the present disclosure and having high heat resistance and piezoelectric properties.

### Solution to Problem

[1] A copolymer having a structural unit represented by the following General Formula (1) and a structural unit represented by the following Formula (2):

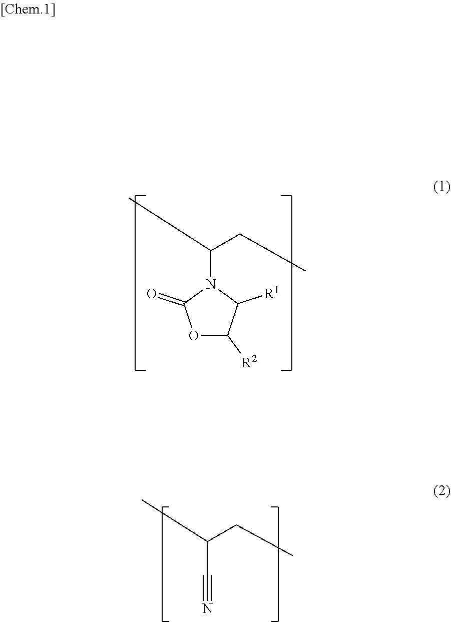

(in General Formula (1), R¹ and R² represent any one selected from the group consisting of a hydrogen atom, a methyl group, a dimethyl group, an ethyl group, an isopropyl group, an isobutyl group, a phenyl group, and a benzyl group, or R¹ and R² form a benzooxazolidinone framework together with an oxazolidinone ring).
[2] The copolymer according to [1],
wherein, in General Formula (1), R¹ represents a hydrogen atom, R² represents one selected from the group consisting of a hydrogen atom, a methyl group, and a dimethyl group, or R¹ represents one selected from the group consisting of a methyl group, a dimethyl group, an ethyl group, and an isopropyl group, and R² represents a hydrogen atom.
   [3] The copolymer according to [1],
wherein, in General Formula (1), R¹ represents a hydrogen atom, and R² represents one selected from the group consisting of a hydrogen atom, a methyl group, and a dimethyl group.
   [4] The copolymer according to [1],
wherein, in General Formula (1), R¹ represents one selected from the group consisting of a methyl group, a dimethyl group, an ethyl group, and an isopropyl group, and R² represents a hydrogen atom.
   [5] The copolymer according to any one of [1] to [4],
wherein the amount of the structural unit represented by Formula (2) is 10 to 80 mol %.
   [6] A piezoelectric material containing the copolymer according to any one of [1] to [5].
   [7] A piezoelectric film containing the copolymer according to any one of [1] to [5].
   [8] A piezoelectric element including the piezoelectric film according to [5] and an electrode disposed on a surface of the piezoelectric film.

### Advantageous Effects of Disclosure

The copolymer of the present disclosure has a structural unit represented by General Formula (1) and a structural unit represented by Formula (2). Therefore, the copolymer of the present disclosure can be used as a piezoelectric material from which a piezoelectric film having high heat resistance and piezoelectric properties can be obtained.

In addition, since the piezoelectric material of the present disclosure contains the copolymer of the present disclosure, a piezoelectric film having high heat resistance and piezoelectric properties can be obtained.

In addition, the piezoelectric film of the present disclosure contains the copolymer of the present disclosure. Therefore, the piezoelectric film of the present disclosure and the piezoelectric element of the present disclosure including the piezoelectric film of the present disclosure have excellent heat resistance and piezoelectric properties.

### BRIEF DESCRIPTION OF DRAWINGS

FIG. 1 is a ¹H-NMR measurement chart of a polymer of Example 1.

FIG. 2 is a ¹H-NMR measurement chart of a polymer of Example 6.

FIG. 3 is a ¹H-NMR measurement chart of a polymer of Example 10.

FIG. 4 is a ¹H-NMR measurement chart of a polymer of Example 14.

FIG. 5 is a ¹H-NMR measurement chart of a polymer of Example 18.

FIG. 6 is a ¹H-NMR measurement chart of a polymer of Example 22.

FIG. 7 is a ¹H-NMR measurement chart of a polymer of Example 27.

### DESCRIPTION OF EMBODIMENTS

In order to address the above problems, the inventors conducted extensive studies, focusing on the heat resistance of polymers using acrylonitrile as raw material monomers.

As a result, it was found that a copolymer having a specific structural unit containing an oxazolidinone framework and a structural unit derived from acrylonitrile may be used.

A compound in which a vinyl group is bonded to a nitrogen atom of an oxazolidinone framework has a high affinity with acrylonitrile. Therefore, the compound in which a vinyl group is bonded to a nitrogen atom of an oxazolidinone framework can form a copolymer with acrylonitrile. In addition, since the compound in which a vinyl group is bonded to a nitrogen atom of an oxazolidinone framework has high polarity, it is copolymerized with acrylonitrile to form a copolymer having better heat resistance than polyacrylonitrile.

Specifically, the dipole moment of the compound containing an oxazolidinone framework is about 6.0 debye, and the dipole moment of acrylonitrile is about 3.8 debye. That is, the structural unit containing an oxazolidinone framework has a higher polarity than the structural unit derived from acrylonitrile. As a result, in the copolymer having a structural unit containing an oxazolidinone framework and a structural unit derived from acrylonitrile, the structural unit containing an oxazolidinone framework with a high polarity disrupts the ordered structure that nitrile groups which are polar groups derived from acrylonitrile can form, and it is difficult to perform alignment for them to cancel out each other's polarities. Accordingly, it is estimated that the copolymer having a structural unit containing an oxazolidinone framework and a structural unit derived from acrylonitrile can be used as a piezoelectric material from which a piezoelectric film having favorable heat resistance and piezoelectric properties can be obtained.

In addition, the inventors have produced a copolymer having a specific structural unit containing an oxazolidinone framework and a structural unit derived from acrylonitrile, confirmed that it had favorable heat resistance and that the piezoelectric film using the copolymer as a piezoelectric material had favorable piezoelectric properties, and completed the present disclosure.

Hereinafter, the copolymer, the piezoelectric material, the piezoelectric film and the piezoelectric element of the present disclosure will be described in detail.

### [Copolymer]

The copolymer of the present embodiment has a structural unit represented by the following General Formula (1) and a structural unit represented by the following Formula (2).

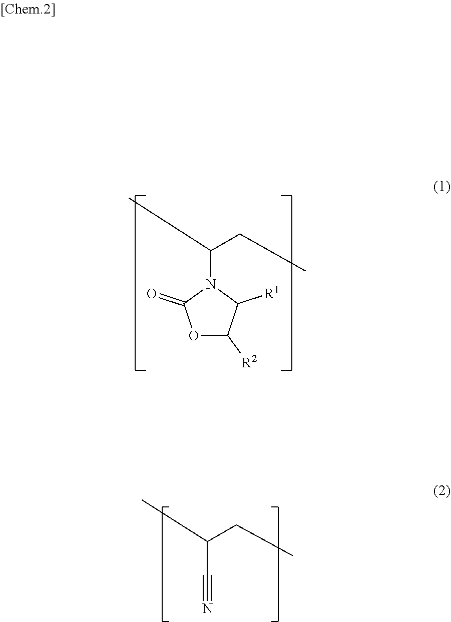

(in General Formula (1), R¹ and R² represent any one selected from the group consisting of a hydrogen atom, a methyl group, a dimethyl group, an ethyl group, an isopropyl group, an isobutyl group, a phenyl group, and a benzyl group, or R¹ and R² form a benzooxazolidinone framework together with an oxazolidinone ring).

In the structural unit represented by Formula (1) of the copolymer of the present embodiment, R¹ and R² represent any one selected from the group consisting of a hydrogen atom, a methyl group, a dimethyl group, an ethyl group, an isopropyl group, an isobutyl group, a phenyl group, and a benzyl group. The copolymer of the present embodiment can be easily produced because R¹ and R² in the structural unit represented by Formula (1) are as described above. In addition, the copolymer of the present embodiment can be used as a material for a piezoelectric film having favorable heat resistance and piezoelectric properties because R¹ and R² in the structural unit represented by Formula (1) are as described above. Since R¹ and R² in the structural unit represented by Formula (1) have no polarity, those having a small volume are preferable. This is because the ratio of the volume of the polar part to the entire copolymer relatively increases, which contributes to improvement of piezoelectric properties of the piezoelectric film using the same.

Specifically, R¹ may represent a hydrogen atom, and R² may represent one selected from the group consisting of a hydrogen atom, a methyl group, and a dimethyl group. Alternatively, R¹ may represent one selected from the group consisting of a methyl group, a dimethyl group, an ethyl group, and an isopropyl group, and R² may represent a hydrogen atom.

Here, R¹ may represent any one selected from the group consisting of a hydrogen atom, a methyl group, a dimethyl group, an ethyl group, an isopropyl group, an isobutyl group, a phenyl group, and a benzyl group, and R² may represent a hydrogen atom or a methyl group. Alternatively, R¹ may represent a hydrogen atom, and R² may represent a hydrogen atom or a methyl group.

In particular, since it can be used as a material for a piezoelectric film having favorable heat resistance and piezoelectric properties, it is particularly preferable that R¹ represent a hydrogen atom and R² represent a methyl group.

The structural unit represented by Formula (1) may be a structural unit in which R¹ and R² form a benzooxazolidinone framework together with an oxazolidinone ring. Even when R¹ and R² in the structural unit represented by Formula (1) of the copolymer of the present embodiment form a benzooxazolidinone framework together with an oxazolidinone ring, it can be easily produced and can be used as a material for a piezoelectric film having favorable heat resistance and piezoelectric properties.

In the copolymer of the present embodiment, the arrangement order of the structural unit represented by Formula (1) and the structural unit represented by Formula (2), which are repeating units, is not particularly limited. In addition, in the copolymer of the present embodiment, the number of structural units represented by Formula (1) and the number of structural units represented by Formula (2) may be the same as or different from each other. Therefore, the copolymer of the present embodiment may be a copolymer in which an alternate arrangement part in which a structural unit represented by Formula (1) and a structural unit represented by Formula (2) are alternately arranged, a random arrangement part in which a structural unit represented by Formula (1) and a structural unit represented by Formula (2) are disorderly arranged, and a block arrangement part including a part in which the structural units represented by Formula (1) are continuously arranged and a part in which the structural units represented by Formula (2) are continuously arranged are distributed at an arbitrary ratio. It is preferable for the copolymer of the present embodiment to include the alternate arrangement part because it is then difficult for nitrile groups contained in the structural unit represented by Formula (2) to be aligned to cancel out each other's polarities and it can be used as a piezoelectric material having favorable heat resistance and piezoelectric properties.

The amount of the structural unit represented by Formula (1) in the copolymer of the present embodiment is preferably 10 to 80 mol %, more preferably 20 to 70 mol %, and still more preferably 30 to 60 mol %. When the amount of the structural unit represented by Formula (1) is 10 mol % or more, a copolymer having better heat resistance is obtained. In addition, when the amount of the structural unit represented by Formula (1) is 80 mol % or less, it is possible to prevent the piezoelectric film containing the copolymer from becoming hard and brittle due to an excessively large amount of the structural unit represented by Formula (1). In addition, when the amount of the structural unit represented by Formula (1) is 80 mol % or less, it is possible to minimize a decrease in the insulation resistance of the copolymer due to absorption of moisture by the structural unit represented by Formula (1).

The amount of the structural unit represented by Formula (2) in the copolymer of the present embodiment is preferably 10 to 80 mol %, more preferably 20 to 70 mol %, and still more preferably 30 to 60 mol %. When the amount of the structural unit represented by Formula (2) is 10 mol % or more, the copolymer has high insulation resistance and can form a flexible piezoelectric film. In addition, when the amount of the structural unit represented by Formula (2) is 80 mol % or less, it is easy to secure the amount of the structural unit represented by Formula (1). As a result, it is difficult for nitrile groups contained in the structural unit represented by Formula (2) to be aligned to cancel out each other's polarities, and the copolymer can form a piezoelectric film having better heat resistance and piezoelectric properties.

The copolymer of the present embodiment may contain, as necessary, one or more structural units other than the structural unit represented by Formula (1) and the structural unit represented by Formula (2). Examples of other structural units include structural units derived from known monomers or oligomers having a polymerizable unsaturated bond.

Among the structural units contained in the copolymer of the present embodiment, the total amount of the structural unit represented by Formula (1) and the structural unit represented by Formula (2) is preferably 50 mass % or more, more preferably 80 mass % or more, and may be 90 mass % or more, and only the structural unit represented by Formula (1) and the structural unit represented by Formula (2) may be used.

The weight average molecular weight (Mw) of the copolymer of the present embodiment is preferably 10,000 to 1,000,000. When the weight average molecular weight (Mw) of the copolymer is 10,000 or more, the copolymer has a favorable film forming property, and a piezoelectric film containing the copolymer of the present embodiment can be easily produced. When the weight average molecular weight (Mw) of the copolymer is 1,000,000 or less, the copolymer can be easily dissolved in a solvent, and a piezoelectric film can be easily produced using a coating solution dissolved in a solvent.

### “Method of Producing Copolymer”

The copolymer of the present embodiment can be produced using, for example, a compound from which the structural unit represented by Formula (1) is derived, raw material monomers containing acrylonitrile, and a polymerization initiator such as azobisisobutyronitrile, by a method of radical copolymerization by a known method.

When the copolymer of the present embodiment is produced, polymerization conditions such as the reaction temperature and the reaction time can be appropriately determined according to the composition of the raw material monomers and the like.

The compounds from which the structural unit represented by Formula (1) is derived are compounds having the same structural unit represented by Formula (1), an oxazolidinone framework and atoms bonded to carbon atoms of the oxazolidinone framework, and having a vinyl group bonded to a nitrogen atom of the oxazolidinone framework. Specific examples of compounds from which the structural unit represented by Formula (1) is derived include N-vinyl-oxazolidinone, N-vinyl-5-methyloxazolidinone, N-vinyl-4-methyloxazolidinone, N-vinyl-4,4-dimethyloxazolidinone, N-vinyl-4-ethyloxazolidinone, N-vinyl-4-propyloxazolidinone, N-vinyl-4-isopropyloxazolidinone, N-vinyl-4-isobutyl oxazolidinone, N-vinyl-4-phenyloxazolidinone, N-vinyl-4-benzyloxazolidinone, and N-vinyl-2-benzoxazolinone, and the compound is appropriately determined according to the structure of the copolymer of the present embodiment which is a desired product.

### “Piezoelectric Material”

The piezoelectric material of the present embodiment contains the copolymer of the present embodiment. The copolymer of the present embodiment contained in the piezoelectric material of the present embodiment may be of only one type or two or more types. In addition, the piezoelectric material of the present embodiment may contain, as necessary, one or more types of known polymers other than the copolymer of the present embodiment together with the copolymer of the present embodiment.

### “Piezoelectric Film”

The piezoelectric film of the present embodiment contains the copolymer of the present embodiment.

The piezoelectric film of the present embodiment can be produced, for example, by the following method. The piezoelectric material of the present embodiment containing the copolymer of the present embodiment is dissolved in a solvent to prepare a coating solution. Next, the coating solution is applied onto a peelable substrate to a predetermined thickness to form a coating. As the substrate, known substrates such as a resin film can be used. As a method of applying a coating solution, a known method can be used depending on a coating thickness, the viscosity of a coating solution and the like. Then, the coating is dried, and the solvent in the coating is removed to obtain a piezoelectric material sheet.

Then, the piezoelectric material sheet is peeled off from the substrate, an electrode made of a known conductive material such as aluminum is disposed on one surface and the other surface of the piezoelectric material sheet, a voltage is applied at a temperature near the glass transition temperature of the piezoelectric material forming the piezoelectric material sheet, and cooling is then performed while the voltage is applied. Thereby, the piezoelectricity is acquired. According to the above process, a sheet-like piezoelectric film is obtained.

The electrode used to acquire the piezoelectricity may be directly used as a member for forming a piezoelectric element or may be removed.

### “Piezoelectric Element”

The piezoelectric element of the present embodiment includes the piezoelectric film of the present embodiment and an electrode disposed on the surface of the piezoelectric film. Specifically, a piezoelectric element including a sheet-like piezoelectric film and an electrode disposed on one surface and the other surface of the piezoelectric film may be exemplified. As the material of the electrode, a known conductive material such as aluminum can be used.

The piezoelectric element of the present embodiment can be produced by, for example, providing an electrode on one surface and the other surface of the piezoelectric film by a known method such as a vapor deposition method.

The copolymer of the present embodiment has a structural unit represented by General Formula (1) and a structural unit represented by Formula (2). Therefore, the copolymer of the present embodiment can be used as a piezoelectric material from which a piezoelectric film having high heat resistance and piezoelectric properties can be obtained.

In addition, since the piezoelectric material of the present embodiment contains the copolymer of the present embodiment, a piezoelectric film having high heat resistance and piezoelectric properties can be obtained.

In addition, the piezoelectric film of the present embodiment contains the copolymer of the present embodiment. Therefore, the piezoelectric film of the present embodiment, and the piezoelectric element of the present embodiment including the piezoelectric film of the present embodiment have excellent heat resistance and piezoelectric properties.

While the embodiments of the present disclosure have been described above in detail, configurations and combinations thereof in the embodiments are only examples, and additions, omissions, substitutions, and other modifications of the configurations can be made without departing from the scope of the present disclosure.

### EXAMPLES

### Example 1

In a 100 ml schlenk tube, 0.4 ml (4 mmol) of N-vinyl-oxazolidinone represented by the following General Formula (11) and 1.2 ml (16 mmol) of acrylonitrile were mixed, 11.5 mg (0.07 mmol) of azobisisobutyronitrile was added thereto, and the mixture was reacted at 60° C. for 2 hours. The reaction product was put into 200 ml of methanol, reprecipitated, filtered, and dried to obtain 1.1 g of a polymer of Example 1. The yield was 78%.

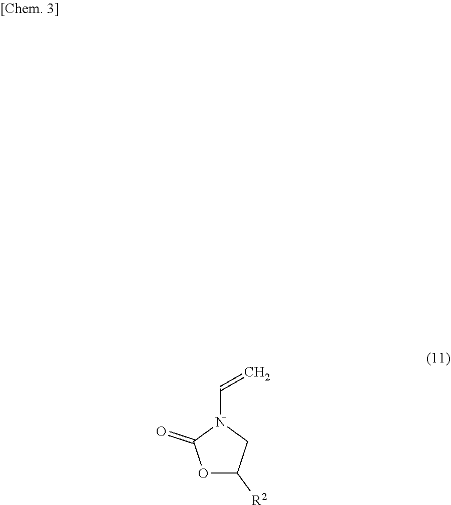

(in General Formula (11), R² represents a hydrogen atom).

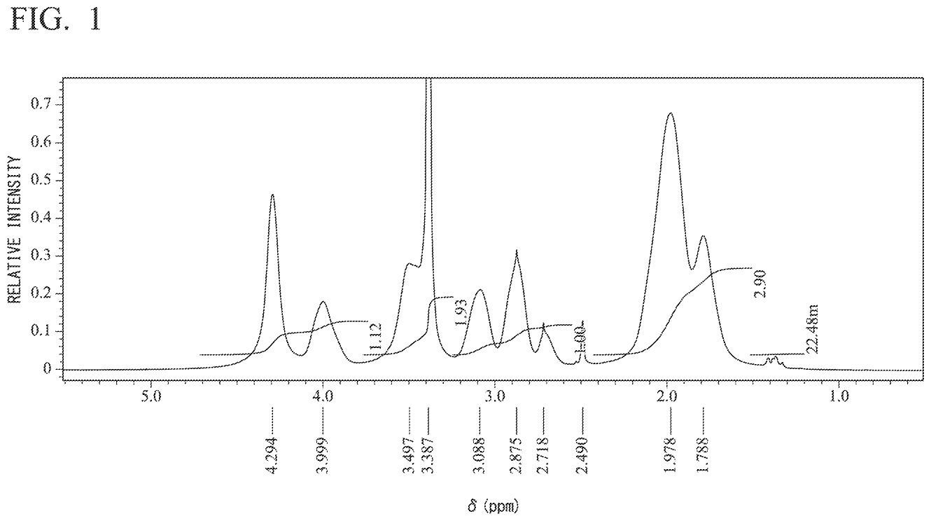

For the polymer of Example 1, 1H-NMR measurement was performed using a nuclear magnetic resonance (NMR) device (product name JNM-ECA500, commercially available from JEOL Ltd.) and using dimethylsulfoxide d6 (DMSO-d6) as a solvent, and the molecular structure was identified. FIG. 1 is a ¹H-NMR measurement chart of the polymer of Example 1.

As a result, it was confirmed that the polymer of Example 1 was a copolymer having a structural unit A represented by General Formula (1) (in General Formula (1), R¹ and R² represent a hydrogen atom) and a structural unit represented by Formula (2).

In addition, the composition ratio was calculated from the integrated value of signals in the ¹H-NMR spectrum of Example 1. As a result, the amount of the structural unit represented by Formula (2) contained in the polymer of Example 1 was 70%.

### Example 2

In a 100 ml schlenk tube, 0.4 ml (4 mmol) of N-vinyl-oxazolidinone and 0.4 ml (7 mmol) of acrylonitrile were mixed, 6.8 mg (0.04 mmol) of azobisisobutyronitrile was added thereto, and the mixture was reacted at 60° C. for 2 hours. The reaction product was put into 200 ml of methanol, reprecipitated, filtered, and dried to obtain 0.5 g of a polymer of Example 3. The yield was 68%.

For the polymer of Example 2, 1H-NMR measurement was performed in the same manner as that of the polymer of Example 1, and the molecular structure was identified. As a result, like the polymer of Example 1, it was confirmed that the polymer of Example 3 was a copolymer having a structural unit A represented by General Formula (1) (in General Formula (1), R¹ and R² represent a hydrogen atom) and a structural unit represented by Formula (2).

In addition, the composition ratio was calculated from the integrated value of signals in the ¹H-NMR spectrum of Example 2. As a result, the amount of the structural unit represented by Formula (2) contained in the polymer of Example 3 was 49%.

### Example 3

In a 100 ml schlenk tube, 0.4 ml (4 mmol) of N-vinyl-oxazolidinone and 0.3 ml (4 mmol) of acrylonitrile were mixed, 5.9 mg (0.04 mmol) of azobisisobutyronitrile was added thereto, and the mixture was reacted at 60° C. for 2 hours. The reaction product was put into 200 ml of methanol, reprecipitated, filtered, and dried to obtain 0.6 g of a polymer of Example 3. The yield was 87%.

For the polymer of Example 3, 1H-NMR measurement was performed in the same manner as that of the polymer of Example 1, and the molecular structure was identified. As a result, like the polymer of Example 1, it was confirmed that the polymer of Example 3 was a copolymer having a structural unit A represented by General Formula (1) (in General Formula (1), R¹ and R² represent a hydrogen atom) and a structural unit represented by Formula (2).

In addition, the composition ratio was calculated from the integrated value of signals in the ¹H-NMR spectrum of Example 3. As a result, the amount of the structural unit represented by Formula (2) contained in the polymer of Example 4 was 24%.

### Example 4

In a 100 ml schlenk tube, 1.2 ml (12 mmol) of N-vinyl-oxazolidinone and 0.1 ml (2 mmol) of acrylonitrile were mixed, 7.9 mg (0.05 mmol) of azobisisobutyronitrile was added thereto, and the mixture was reacted at 60° C. for 2 hours. The reaction product was put into 200 ml of methanol, reprecipitated, filtered, and dried to obtain 1.1 g of a polymer of Example 4. The yield was 73%.

For the polymer of Example 4, ¹H-NMR measurement was performed in the same manner as that of the polymer of Example 1, and the molecular structure was identified. As a result, like the polymer of Example 1, it was confirmed that the polymer of Example 4 was a copolymer having a structural unit A represented by General Formula (1) (in General Formula (1), R¹ and R² represent a hydrogen atom) and a structural unit represented by Formula (2).

In addition, the composition ratio was calculated from the integrated value of signals in the ¹H-NMR spectrum of Example 4. As a result, the amount of the structural unit represented by Formula (2) contained in the polymer of Example 4 was 14%.

### Example 5

In a 100 ml schlenk tube, 0.6 ml (5 mmol) of N-vinyl-4-methyl-oxazolidinone and 0.7 ml (10 mmol) of acrylonitrile were mixed, 9.4 mg (0.06 mmol) of azobisisobutyronitrile was added thereto, and the mixture was reacted at 60° C. for 2 hours. The reaction product was put into 200 ml of methanol, reprecipitated, filtered, and dried to obtain 0.5 g of a polymer of Example 5. The yield was 44%.

For the polymer of Example 5, 1H-NMR measurement was performed in the same manner as that of the polymer of Example 1, and the molecular structure was identified. As a result, it was conformed that the polymer of Example 5 was a copolymer having a structural unit B represented by General Formula (1) (in General Formula (1), R¹ represents a methyl group, and R² represents a hydrogen atom) and a structural unit represented by Formula (2).

In addition, the composition ratio was calculated from the integrated value of signals in the ¹H-NMR spectrum of Example 5. As a result, the amount of the structural unit represented by Formula (2) contained in the polymer of Example 5 was 75%.

### Example 6

In a 100 ml schlenk tube, 0.6 ml (5 mmol) of N-vinyl-4-methyl-oxazolidinone and 0.3 ml (5 mmol) of acrylonitrile were mixed, 7.4 mg (0.04 mmol) of azobisisobutyronitrile was added thereto, and the mixture was reacted at 60° C. for 2 hours. The reaction product was put into 200 ml of methanol, reprecipitated, filtered, and dried to obtain 0.7 g of a polymer of Example 6. The yield was 68%.

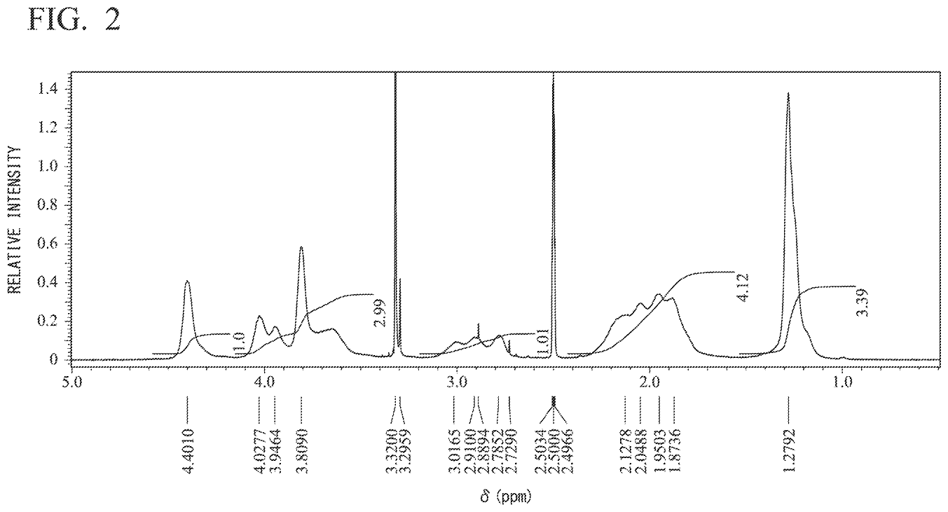

For the polymer of Example 6, ¹H-NMR measurement was performed in the same manner as that of the polymer of Example 1, and the molecular structure was identified. FIG. 2 is a ¹H-NMR measurement chart of the polymer of Example 6.

As a result, like the Example 5, it was confirmed that the polymer of Example 6 was a copolymer having a structural unit B represented by General Formula (1) (in General Formula (1), R¹ represents a methyl group, and R² represents a hydrogen atom) and a structural unit represented by Formula (2).

In addition, the composition ratio was calculated from the integrated value of signals in the ¹H-NMR spectrum of Example 6. As a result, the amount of the structural unit represented by Formula (2) contained in the polymer of Example 6 was 55%.

### Example 7

In a 100 ml schlenk tube, 0.6 ml (5 mmol) of N-vinyl-4-methyl-oxazolidinone and 0.7 ml (10 mmol) of acrylonitrile were mixed, 9.4 mg (0.06 mmol) of azobisisobutyronitrile was added thereto, and the mixture was reacted at 60° C. for 2 hours. The reaction product was put into 200 ml of methanol, reprecipitated, filtered, and dried to obtain 0.7 g of a polymer of Example 7. The yield was 59%.

For the polymer of Example 7, ¹H-NMR measurement was performed in the same manner as that of the polymer of Example 1, and the molecular structure was identified. As a result, like Example 5, it was confirmed that the polymer of Example 7 was a copolymer having a structural unit B represented by General Formula (1) (in General Formula (1), R¹ represents a methyl group, and R² represents a hydrogen atom) and a structural unit represented by Formula (2).

In addition, the composition ratio was calculated from the integrated value of signals in the ¹H-NMR spectrum of Example 7. As a result, the amount of the structural unit represented by Formula (2) contained in the polymer of Example 7 was 33%.

### Example 8

In a 100 ml schlenk tube, 1.2 ml (10 mmol) of N-vinyl-4-methyl-oxazolidinone and 0.1 ml (2 mmol) of acrylonitrile were mixed, 11.2 mg (0.07 mmol) of azobisisobutyronitrile was added thereto, and the mixture was reacted at 60° C. for 2 hours. The reaction product was put into 200 ml of methanol, reprecipitated, filtered, and dried to obtain 0.9 g of a polymer of Example 8. The yield was 62%.

For the polymer of Example 8, 1H-NMR measurement was performed in the same manner as that of the polymer of Example 1, and the molecular structure was identified. As a result, like Example 5, it was confirmed that the polymer of Example 8 was a copolymer having a structural unit B represented by General Formula (1) (in General Formula (1), R¹ represents a methyl group, and R² represents a hydrogen atom) and a structural unit represented by Formula (2).

In addition, the composition ratio was calculated from the integrated value of signals in the ¹H-NMR spectrum of Example 8. As a result, the amount of the structural unit represented by Formula (2) contained in the polymer of Example 8 was 14%.

### Example 9

In a 100 ml schlenk tube, 0.6 ml (5 mmol) of N-vinyl-4-ethyl-oxazolidinone and 0.6 ml (10 mmol) of acrylonitrile were mixed, 9.8 mg (0.06 mmol) of azobisisobutyronitrile was added thereto, and the mixture was reacted at 60° C. for 2 hours. The reaction product was put into 200 ml of methanol, reprecipitated, filtered, and dried to obtain 0.7 g of a polymer of Example 9. The yield was 55%.

For the polymer of Example 9, 1H-NMR measurement was performed in the same manner as that of the polymer of Example 1, and the molecular structure was identified. As a result, it was confirmed that the polymer of Example 9 was a copolymer having a structural unit C represented by General Formula (1) (in General Formula (1), R¹ represents an ethyl group, R² represents a hydrogen atom) and a structural unit represented by Formula (2).

In addition, the composition ratio was calculated from the integrated value of signals in the ¹H-NMR spectrum of Example 9. As a result, the amount of the structural unit represented by Formula (2) contained in the polymer of Example 9 was 73%.

### Example 10

In a 100 ml schlenk tube, 0.6 ml (5 mmol) of N-vinyl-4-ethyl-oxazolidinone and 0.3 ml (5 mmol) of acrylonitrile were mixed, 7.7 mg (0.05 mmol) of azobisisobutyronitrile was added thereto, and the mixture was reacted at 60° C. for 2 hours. The reaction product was put into 200 ml of methanol, reprecipitated, filtered, and dried to obtain 0.4 g of a polymer of Example 10. The yield was 44%.

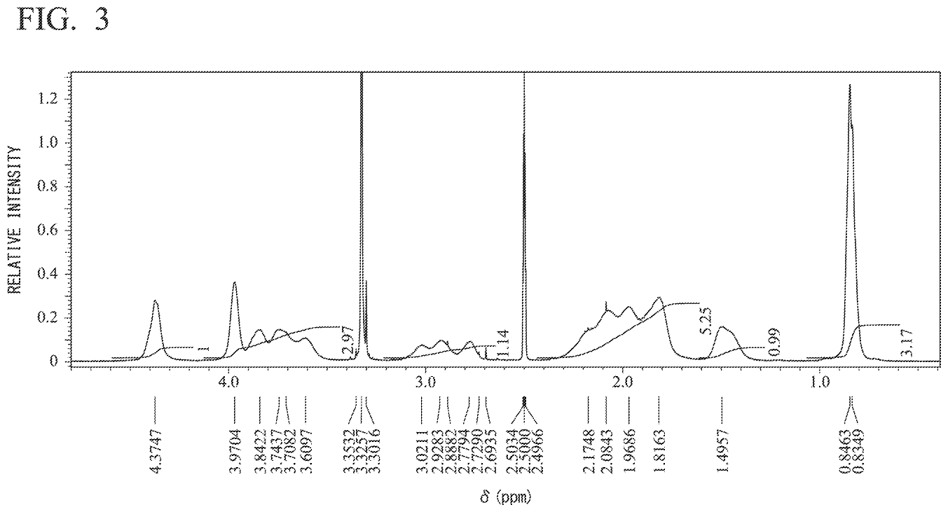

For the polymer of Example 10, 1H-NMR measurement was performed in the same manner as that of the polymer of Example 1, and the molecular structure was identified. FIG. 3 is a ¹H-NMR measurement chart of the polymer of Example 10.

As a result, like Example 9, it was confirmed that the polymer of Example 10 was a copolymer having a structural unit C represented by General Formula (1) (in General Formula (1), R¹ represents an ethyl group, and R² represents a hydrogen atom) and a structural unit represented by Formula (2).

In addition, the composition ratio was calculated from the integrated value of signals in the ¹H-NMR spectrum of Example 10. As a result, the amount of the structural unit represented by Formula (2) contained in the polymer of Example 10 was 60%.

### Example 11

In a 100 ml schlenk tube, 0.6 ml (5 mmol) of N-vinyl-4-ethyl-oxazolidinone and 0.1 ml (2 mmol) of acrylonitrile were mixed, 6.4 mg (0.06 mmol) of azobisisobutyronitrile was added thereto, and the mixture was reacted at 60° C. for 2 hours. The reaction product was put into 200 ml of methanol, reprecipitated, filtered, and dried to obtain 0.5 g of a polymer of Example 11. The yield was 62%.

For the polymer of Example 11, 1H-NMR measurement was performed in the same manner as that of the polymer of Example 1, and the molecular structure was identified. As a result, like Example 9, it was confirmed that the polymer of Example 11 was a copolymer having a structural unit C represented by General Formula (1) (in General Formula (1), R¹ represents an ethyl group and R² represents a hydrogen atom) and a structural unit represented by Formula (2).

In addition, the composition ratio was calculated from the integrated value of signals in the ¹H-NMR spectrum of Example 11. As a result, the amount of the structural unit represented by Formula (2) contained in the polymer of Example 11 was 39%.

### Example 12

In a 100 ml schlenk tube, 1.2 ml (10 mmol) of N-vinyl-4-ethyl-oxazolidinone and 0.1 ml (2 mmol) of acrylonitrile were mixed, 12.0 mg (0.07 mmol) of azobisisobutyronitrile was added thereto, and the mixture was reacted at 60° C. for 2 hours. The reaction product was put into 200 ml of methanol, reprecipitated, filtered, and dried to obtain 0.7 g of a polymer of Example 12. The yield was 45%.

For the polymer of Example 12, ¹H-NMR measurement was performed in the same manner as that of the polymer of Example 1, and the molecular structure was identified. As a result, like Example 9, it was confirmed that the polymer of Example 12 was a copolymer having a structural unit C represented by General Formula (1) (in General Formula (1), R¹ represents an ethyl group and R² represents a hydrogen atom) and a structural unit represented by Formula (2).

In addition, the composition ratio was calculated from the integrated value of signals in the ¹H-NMR spectrum of Example 12. As a result, the amount of the structural unit represented by Formula (2) contained in the polymer of Example 12 was 21%.

### Example 13

In a 100 ml schlenk tube, 0.7 ml (5 mmol) of N-vinyl-4-isopropyl-oxazolidinone and 0.7 ml (10 mmol) of acrylonitrile were mixed, 10.2 mg (0.06 mmol) of azobisisobutyronitrile was added thereto, and the mixture was reacted at 60° C. for 2 hours. The reaction product was put into 200 ml of methanol, reprecipitated, filtered, and dried to obtain 0.7 g of a polymer of Example 13. The yield was 55%.

For the polymer of Example 13, 1H-NMR measurement was performed in the same manner as that of the polymer of Example 1, and the molecular structure was identified. As a result, it was confirmed that the polymer of Example 13 was a copolymer having a structural unit D represented by General Formula (1) (in General Formula (1), R¹ represents an isopropyl group (iPr) and R² represents a hydrogen atom) and a structural unit represented by Formula (2).

In addition, the composition ratio was calculated from the integrated value of signals in the ¹H-NMR spectrum of Example 13. As a result, the amount of the structural unit represented by Formula (2) contained in the polymer of Example 13 was 67%.

### Example 14

In a 100 ml schlenk tube, 0.6 ml (5 mmol) of N-vinyl-4-isopropyl-oxazolidinone and 0.3 ml (5 mmol) of acrylonitrile were mixed, 7.5 mg (0.05 mmol) of azobisisobutyronitrile was added thereto, and the mixture was reacted at 60° C. for 2 hours. The reaction product was put into 200 ml of methanol, reprecipitated, filtered, and dried to obtain 0.6 g of a polymer of Example 14. The yield was 66%.

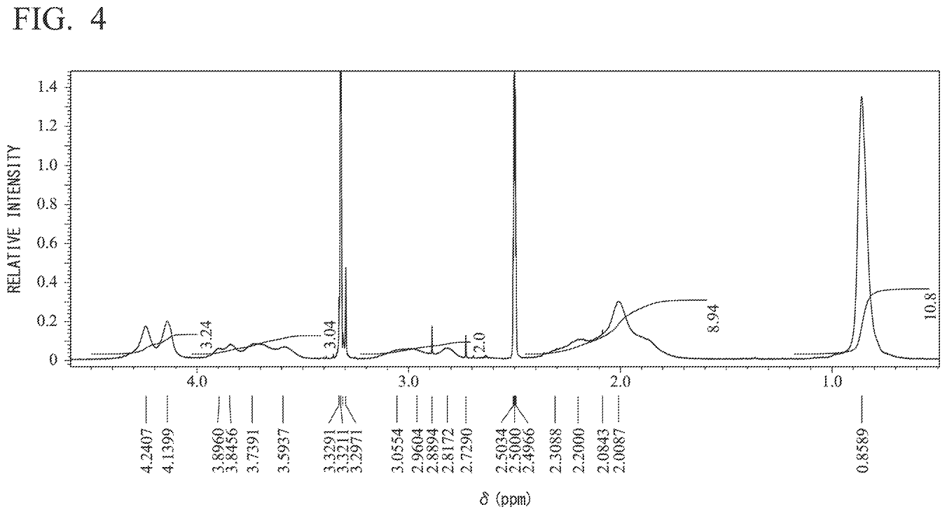

For the polymer of Example 14, ¹H-NMR measurement was performed in the same manner as that of the polymer of Example 1, and the molecular structure was identified. FIG. 4 is a ¹H-NMR measurement chart of the polymer of Example 14.

As a result, like Example 13, it was confirmed that the polymer of Example 14 was a copolymer having a structural unit D represented by General Formula (1) (in General Formula (1), R¹ represents an isopropyl group (iPr) and R² represents a hydrogen atom) and a structural unit represented by Formula (2).

In addition, the composition ratio was calculated from the integrated value of signals in the ¹H-NMR spectrum of Example 14. As a result, the amount of the structural unit represented by Formula (2) contained in the polymer of Example 14 was 44%.

### Example 15

In a 100 ml schlenk tube, 0.7 ml (5 mmol) of N-vinyl-4-isopropyl-oxazolidinone and 0.1 ml (2 mmol) of acrylonitrile were mixed, 6.8 mg (0.04 mmol) of azobisisobutyronitrile was added thereto, and the mixture was reacted at 60° C. for 2 hours.

The reaction product was put into 200 ml of methanol, reprecipitated, filtered, and dried to obtain 0.6 g of a polymer of Example 15. The yield was 72%.

For the polymer of Example 15, 1H-NMR measurement was performed in the same manner as that of the polymer of Example 1, and the molecular structure was identified. As a result, like Example 13, it was confirmed that the polymer of Example 15 was a copolymer having a structural unit D represented by General Formula (1) (in General Formula (1), R¹ represents an isopropyl group (iPr) and R² represents a hydrogen atom) and a structural unit represented by Formula (2).

In addition, the composition ratio was calculated from the integrated value of signals in the ¹H-NMR spectrum of Example 15. As a result, the amount of the structural unit represented by Formula (2) contained in the polymer of Example 15 was 32%.

### Example 16

In a 100 ml schlenk tube, 1.4 ml (10 mmol) of N-vinyl-4-isopropyl-oxazolidinone and 0.1 ml (2 mmol) of acrylonitrile were mixed, 13.2 mg (0.08 mmol) of azobisisobutyronitrile was added thereto, and the mixture was reacted at 60° C. for 2 hours. The reaction product was put into 200 ml of methanol, reprecipitated, filtered, and dried to obtain 0.9 g of a polymer of Example 16. The yield was 57%.

For the polymer of Example 16, ¹H-NMR measurement was performed in the same manner as that of the polymer of Example 1, and the molecular structure was identified. As a result, like Example 13, it was confirmed that the polymer of Example 16 was a copolymer having a structural unit D represented by General Formula (1) (in General Formula (1), R¹ represents an isopropyl group (iPr) and R² represents a hydrogen atom) and a structural unit represented by Formula (2).

In addition, the composition ratio was calculated from the integrated value of signals in the ¹H-NMR spectrum of Example 16. As a result, the amount of the structural unit represented by Formula (2) contained in the polymer of Example 16 was 18%.

### Example 17

In a 100 ml schlenk tube, 0.8 ml (6 mmol) of N-vinyl-4,4-dimethyl-oxazolidinone and 0.8 ml (12 mmol) of acrylonitrile were mixed, 12.6 mg (0.08 mmol) of azobisisobutyronitrile was added thereto, and the mixture was reacted at 60° C. for 2 hours. The reaction product was put into 200 ml of methanol, reprecipitated, filtered, and dried to obtain 0.8 g of a polymer of Example 17. The yield was 50%.

For the polymer of Example 17, 1H-NMR measurement was performed in the same manner as that of the polymer of Example 1, and the molecular structure was identified. As a result, it was confirmed that the polymer of Example 17 was a copolymer having a structural unit E represented by General Formula (1) (in General Formula (1), R¹ represents a dimethyl group and R² represents a hydrogen atom) and a structural unit represented by Formula (2).

In addition, the composition ratio was calculated from the integrated value of signals in the ¹H-NMR spectrum of Example 17. As a result, the amount of the structural unit represented by Formula (2) contained in the polymer of Example 17 was 73%.

### Example 18

In a 100 ml schlenk tube, 0.8 ml (6 mmol) of N-vinyl-4,4-dimethyl-oxazolidinone and 0.4 ml (6 mmol) of acrylonitrile were mixed, 9.9 mg (0.06 mmol) of azobisisobutyronitrile was added thereto, and the mixture was reacted at 60° C. for 2 hours. The reaction product was put into 200 ml of methanol, reprecipitated, filtered, and dried to obtain 0.7 g of a polymer of Example 18. The yield was 53%.

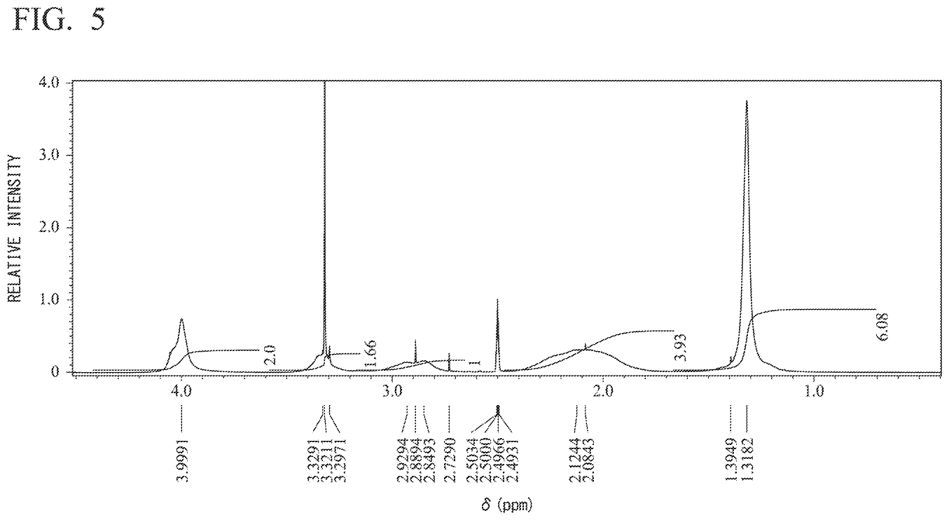

For the polymer of Example 18, ¹H-NMR measurement was performed in the same manner as that of the polymer of Example 1, and the molecular structure was identified. FIG. 5 is a ¹H-NMR measurement chart of the polymer of Example 18.

As a result, like Example 17, it was confirmed that the polymer of Example 18 was a copolymer having a structural unit E represented by General Formula (1) (in General Formula (1), R¹ represents a dimethyl group and R² represents a hydrogen atom) and a structural unit represented by Formula (2).

In addition, the composition ratio was calculated from the integrated value of signals in the ¹H-NMR spectrum of Example 18. As a result, the amount of the structural unit represented by Formula (2) contained in the polymer of Example 18 was 50%.

### Example 19

In a 100 ml schlenk tube, 0.8 ml (6 mmol) of N-vinyl-4,4-dimethyl-oxazolidinone and 0.2 ml (3 mmol) of acrylonitrile were mixed, 8.6 mg (0.05 mmol) of azobisisobutyronitrile was added thereto, and the mixture was reacted at 60° C. for 2 hours. The reaction product was put into 200 ml of methanol, reprecipitated, filtered, and dried to obtain 0.4 g of a polymer of Example 19. The yield was 41%.

For the polymer of Example 19, 1H-NMR measurement was performed in the same manner as that of the polymer of Example 1, and the molecular structure was identified. As a result, like Example 17, it was confirmed that the polymer of Example 19 was a copolymer having a structural unit E represented by General Formula (1) (in General Formula (1), R¹ represents a dimethyl group and R² represents a hydrogen atom) and a structural unit represented by Formula (2).

In addition, the composition ratio was calculated from the integrated value of signals in the ¹H-NMR spectrum of Example 19. As a result, the amount of the structural unit represented by Formula (2) contained in the polymer of Example 19 was 33%.

### Example 20

In a 100 ml schlenk tube, 1 ml (8 mmol) of N-vinyl-4,4-dimethyl-oxazolidinone and 0.1 ml (2 mmol) of acrylonitrile were mixed, 10.0 mg (0.06 mmol) of azobisisobutyronitrile was added thereto, and the mixture was reacted at 60° C. for 2 hours. The reaction product was put into 200 ml of methanol, reprecipitated, filtered, and dried to obtain 0.8 g of a polymer of Example 20. The yield was 61%.

For the polymer of Example 20, ¹H-NMR measurement was performed in the same manner as that of the polymer of Example 1, and the molecular structure was identified. As a result, like Example 17, it was confirmed that the polymer of Example 20 was a copolymer having a structural unit E represented by General Formula (1) (in General Formula (1), R¹ represents a dimethyl group and R² represents a hydrogen atom) and a structural unit represented by Formula (2).

In addition, the composition ratio was calculated from the integrated value of signals in the ¹H-NMR spectrum of Example 20. As a result, the amount of the structural unit represented by Formula (2) contained in the polymer of Example 20 was 17%.

### Example 21

In a 100 ml schlenk tube, 0.5 ml (4 mmol) of N-vinyl-5-methyloxazolidinone (a compound in which R² in General Formula (11) represents a methyl group) and 1.0 ml (16 mmol) of acrylonitrile were mixed, 10.7 mg (0.07 mmol) of azobisisobutyronitrile was added thereto, and the mixture was reacted at 60° C. for 2 hours. The reaction product was put into 200 ml of methanol, reprecipitated, filtered, and dried to obtain 0.9 g of a polymer of Example 21. The yield was 68%.

For the polymer of Example 21, ¹H-NMR measurement was performed in the same manner as that of the polymer of Example 1, and the molecular structure was identified. As a result, it was confirmed that the polymer of Example 21 was a copolymer having a structural unit F represented by General Formula (1) (in General Formula (1), R¹ represents a hydrogen atom, and R² represents a methyl group) and a structural unit represented by Formula (2).

In addition, the composition ratio was calculated from the integrated value of signals in the ¹H-NMR spectrum of Example 21. As a result, the amount of the structural unit represented by Formula (2) contained in the polymer of Example 6 was 76%.

### Example 22

In a 100 ml schlenk tube, 1.4 ml (12 mmol) of N-vinyl-5-methyloxazolidinone and 1.0 ml (16 mmol) of acrylonitrile were mixed, 10.8 mg (0.07 mmol) of azobisisobutyronitrile was added thereto, and the mixture was reacted at 60° C. for 2 hours. The reaction product was put into 200 ml of methanol, reprecipitated, filtered, and dried to obtain 1.5 g of a polymer of Example 22. The yield was 67%.

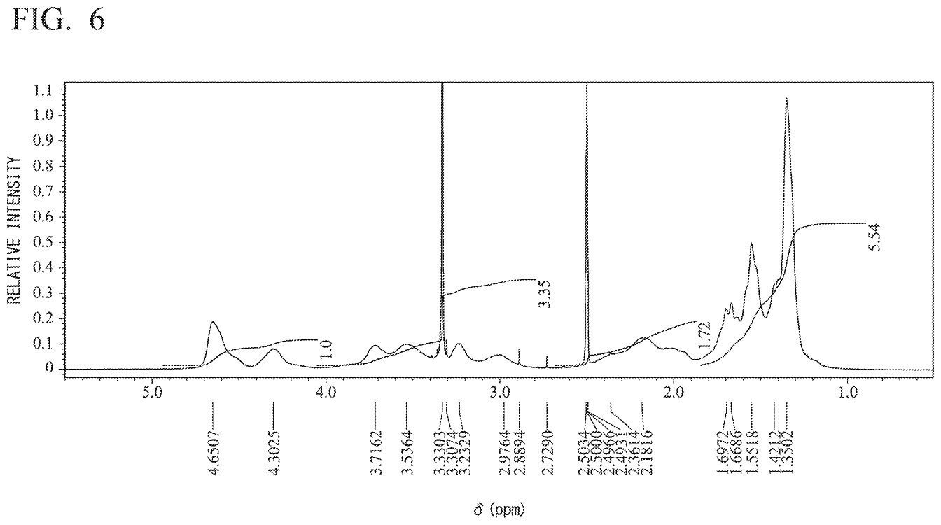

For the polymer of Example 22, ¹H-NMR measurement was performed in the same manner as that of the polymer of Example 1, and the molecular structure was identified. FIG. 6 is a ¹H-NMR measurement chart of the polymer of Example 22.

As a result, like the polymer of Example 21, it was confirmed that the polymer of Example 22 was a copolymer having a structural unit F represented by General Formula (1) (in General Formula (1), R¹ represents a hydrogen atom, and R² represents a methyl group) and a structural unit represented by Formula (2).

In addition, the composition ratio was calculated from the integrated value of signals in the ¹H-NMR spectrum of Example 22. As a result, the amount of the structural unit represented by Formula (2) contained in the polymer of Example 22 was 44%.

### Example 23

In a 100 ml schlenk tube, 1.4 ml (12 mmol) of N-vinyl-5-methyloxazolidinone and 0.8 ml (12 mmol) of acrylonitrile were mixed, 9.1 mg (0.06 mmol) of azobisisobutyronitrile was added thereto, and the mixture was reacted at 60° C. for 2 hours. The reaction product was put into 200 ml of methanol, reprecipitated, filtered, and dried to obtain 1.3 g of a polymer of Example 23. The yield was 60%.

For the polymer of Example 23, 1H-NMR measurement was performed in the same manner as that of the polymer of Example 1, and the molecular structure was identified. As a result, like the polymer of Example 21, it was confirmed that the polymer of Example 23 was a copolymer having a structural unit F represented by General Formula (1) (in General Formula (1), R¹ represents a hydrogen atom, and R² represents a methyl group) and a structural unit represented by Formula (2).

In addition, the composition ratio was calculated from the integrated value of signals in the ¹H-NMR spectrum of Example 23. As a result, the amount of the structural unit represented by Formula (2) contained in the polymer of Example 23 was 28%.

### Example 24

In a 100 ml schlenk tube, 1.4 ml (12 mmol) of N-vinyl-5-methyloxazolidinone and 0.4 ml (6 mmol) of acrylonitrile were mixed, 14.8 mg (0.09 mmol) of azobisisobutyronitrile was added thereto, and the mixture was reacted at 60° C. for 2 hours. The reaction product was put into 200 ml of methanol, reprecipitated, filtered, and dried to obtain 1.1 g of a polymer of Example 24. The yield was 60%.

For the polymer of Example 24, ¹H-NMR measurement was performed in the same manner as that of the polymer of Example 1, and the molecular structure was identified. As a result, like the polymer of Example 21, it was confirmed that the polymer of Example 24 was a copolymer having a structural unit F represented by General Formula (1) (in General Formula (1), R¹ represents a hydrogen atom, and R² represents a methyl group) and a structural unit represented by Formula (2).

In addition, the composition ratio was calculated from the integrated value of signals in the ¹H-NMR spectrum of Example 24. As a result, the amount of the structural unit represented by Formula (2) contained in the polymer of Example 24 was 13%.

### Example 25

In a 100 ml schlenk tube, 0.5 ml (4 mmol) of N-vinyl-5,5-dimethyl-oxazolidinone and 1 ml (16 mmol) of acrylonitrile were mixed, 11.2 mg (0.07 mmol) of azobisisobutyronitrile was added thereto, and the mixture was reacted at 60° C. for 2 hours. The reaction product was put into 200 ml of methanol, reprecipitated, filtered, and dried to obtain 0.8 g of a polymer of Example 25. The yield was 54%.

For the polymer of Example 25, ¹H-NMR measurement was performed in the same manner as that of the polymer of Example 1, and the molecular structure was identified. As a result, it was confirmed that the polymer of Example 25 was a copolymer having a structural unit G represented by General Formula (1) (in General Formula (1), R¹ represents a hydrogen atom, and R² represents a dimethyl group) and a structural unit represented by Formula (2).

In addition, the composition ratio was calculated from the integrated value of signals in the ¹H-NMR spectrum of Example 25. As a result, the amount of the structural unit represented by Formula (2) contained in the polymer of Example 25 was 74%.

### Example 26

In a 100 ml schlenk tube, 1.5 ml (12 mmol) of N-vinyl-5,5-dimethyl-oxazolidinone and 1 ml (16 mmol) of acrylonitrile were mixed, 20.4 mg (0.12 mmol) of azobisisobutyronitrile was added thereto, and the mixture was reacted at 60° C. for 2 hours. The reaction product was put into 200 ml of methanol, reprecipitated, filtered, and dried to obtain 1.1 g of a polymer of Example 26. The yield was 45%.

For the polymer of Example 26, ¹H-NMR measurement was performed in the same manner as that of the polymer of Example 1, and the molecular structure was identified. As a result, like Example 25, it was confirmed that the polymer of Example 26 was a copolymer having a structural unit G represented by General Formula (1) (in General Formula (1), R¹ represents a hydrogen atom, and R² represents a dimethyl group) and a structural unit represented by Formula (2).

In addition, the composition ratio was calculated from the integrated value of signals in the ¹H-NMR spectrum of Example 26. As a result, the amount of the structural unit represented by Formula (2) contained in the polymer of Example 26 was 58%.

### Example 27

In a 100 ml schlenk tube, 1.5 ml (12 mmol) of N-vinyl-5,5-dimethyl-oxazolidinone and 0.8 ml (12 mmol) of acrylonitrile were mixed, 18.7 mg (0.11 mmol) of azobisisobutyronitrile was added thereto, and the mixture was reacted at 60° C. for 2 hours. The reaction product was put into 200 ml of methanol, reprecipitated, filtered, and dried to obtain 0.9 g of a polymer of Example 27. The yield was 38%.

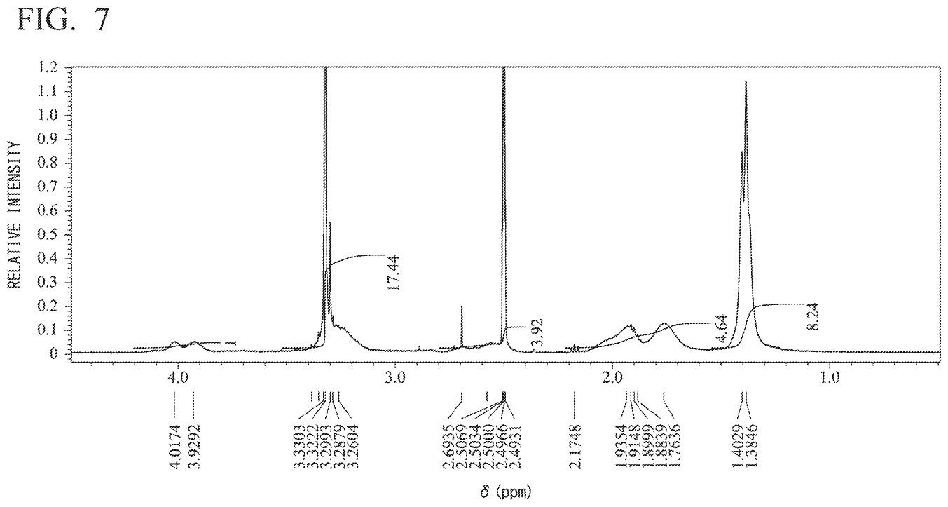

For the polymer of Example 27, 1H-NMR measurement was performed in the same manner as that of the polymer of Example 1, and the molecular structure was identified. FIG. 7 is a ¹H-NMR measurement chart of the polymer of Example 27.

As a result, like Example 25, it was confirmed that the polymer of Example 27 was a copolymer having a structural unit G represented by General Formula (1) (in General Formula (1), R¹ represents a hydrogen atom, and R² represents a dimethyl group) and a structural unit represented by Formula (2).

In addition, the composition ratio was calculated from the integrated value of signals in the ¹H-NMR spectrum of Example 27. As a result, the amount of the structural unit represented by Formula (2) contained in the polymer of Example 27 was 41%.

### Example 28

In a 100 ml schlenk tube, 1.5 ml (12 mmol) of N-vinyl-5,5-dimethyl-oxazolidinone and 0.4 ml (6 mmol) of acrylonitrile were mixed, and 16.1 mg (0.10 mmol) of azobisisobutyronitrile was added thereto, and the mixture was reacted at 60° C. for 2 hours. The reaction product was put into 200 ml of methanol, reprecipitated, filtered, and dried to obtain 1.0 g of a polymer of Example 28. The yield was 49%.

For the polymer of Example 28, 1H-NMR measurement was performed in the same manner as that of the polymer of Example 1, and the molecular structure was identified. As a result, like Example 25, it was confirmed that the polymer of Example 28 was a copolymer having a structural unit G represented by General Formula (1) (in General Formula (1), R¹ represents a hydrogen atom, and R² represents a dimethyl group) and a structural unit represented by Formula (2).

In addition, the composition ratio was calculated from the integrated value of signals in the ¹H-NMR spectrum of Example 28. As a result, the amount of the structural unit represented by Formula (2) contained in the polymer of Example 28 was 19%.

### Comparative Example 1

A polyacrylonitrile (product name 181315, commercially available from Sigma-Aldrich) was used as the polymer of Comparative Example 1.

### Comparative Example 2

Poly(acrylonitrile-CO-methylacrylate) (product name 517941, commercially available from Sigma-Aldrich) was used as the polymer of Comparative Example 2.

For the polymers of Example 1 to Example 28 obtained in this manner, R² in the structural unit represented by General Formula (1) and the amount of the structural unit represented by Formula (2) are shown in Table 1.

In addition, Table 1 shows compound names of the polymers of Comparative Example 1 and Comparative Example 2.

TABLE 1

| | | Amount of | | |
|---|---|---|---|---|
| | | structural | | |
| | | unit | Glass | |
| | | represented | transition | |
| | R¹ and R² in structural unit represented | by Formula | temperature | d₃₃ |
| | by Formula (1) or polymer name | (2) (mol %) | (° C.) | (pC/N) |
| Example 1 | A(R¹ = H, R² = H) | 70% | 132 | 1.7 |
| Example 2 | A(R¹ = H, R² = H) | 49% | 140 | 3.2 |
| Example 3 | A(R¹ = H, R² = H) | 24% | 151 | 2.6 |
| Example 4 | A(R¹ = H, R² = H) | 14% | 160 | 1.6 |
| Example 5 | B(R¹ = CH₃, R² = H) | 75% | 143 | 1.8 |
| Example 6 | B(R¹ = CH₃, R² = H) | 55% | 170 | 3.3 |
| Example 7 | B(R¹ = CH₃, R² = H) | 33% | 197 | 1.9 |
| Example 8 | B(R¹ = CH₃, R² = H) | 14% | 222 | 1.3 |
| Example 9 | C(R¹ = CH₂CH₃, R² = H) | 73% | 141 | 2 |
| Example 10 | C(R¹ = CH₂CH₃, R² = H) | 60% | 155 | 3.5 |
| Example 11 | C(R¹ = CH₂CH₃, R² = H) | 39% | 180 | 2.9 |
| Example 12 | C(R¹ = CH₂CH₃, R² = H) | 21% | 200 | 2.2 |
| Example 13 | D(R¹ = iPr, R² = H) | 67% | 148 | 1.8 |
| Example 14 | D(R¹ = iPr, R² = H) | 44% | 174 | 2.9 |
| Example 15 | D(R¹ = iPr, R² = H) | 32% | 188 | 2.4 |
| Example 16 | D(R¹ = iPr, R² = H) | 18% | 204 | 1.3 |
| Example 17 | E(R¹ = dimethyl, R² = H) | 73% | 156 | 2.8 |
| Example 18 | E(R¹ = dimethyl, R² = H) | 50% | 195 | 3.9 |
| Example 19 | E(R¹ = dimethyl, R² = H) | 33% | 224 | 1.8 |
| Example 20 | E(R¹ = dimethyl, R² = H) | 17% | 251 | 1.1 |
| Example 21 | F(R¹ = H, R² = CH₃) | 76% | 138 | 2.2 |
| Example 22 | F(R¹ = H, R² = CH₃) | 44% | 159 | 3.9 |
| Example 23 | F(R¹ = H, R² = CH₃) | 28% | 174 | 3.5 |
| Example 24 | F(R¹ = H, R² = CH₃) | 13% | 184 | 2.9 |
| Example 25 | G(R¹ = H, R² = dimethyl) | 74% | 143 | 2 |
| Example 26 | G(R¹ = H, R² = dimethyl) | 58% | 163 | 3.6 |
| Example 27 | G(R¹ = H, R² = dimethyl) | 41% | 184 | 3.1 |
| Example 28 | G(R¹ = H, R² = dimethyl) | 19% | 211 | 2.3 |
| Comparative | Polyacrylonitrile | 100% | 98 | 0.8 |
| Example 1 | | | | |
| Comparative | Poly(acrylonitrile-co-methylacrylate) | 96% | 97 | 0.7 |
| Example 2 | | | | |

For the polymers of Example 1 to Example 28, Comparative Example 1, and Comparative Example 2, the glass transition temperature (Tg) was measured by the following method. The results are shown in Table 1.

### (Method of Measuring Glass Transition Temperature (Tg))

Using a high sensitivity differential scanning calorimeter (product name, DSC6200, commercially available from Seiko Instruments Inc.), under a nitrogen atmosphere, a temperature rising and dropping operation was performed at a temperature rise rate of 20° C./min from 30° C. to 200° C., a temperature drop rate of 40° C./min from 200° C. to 30° C., and a temperature rise rate of 20° C./min from 30° C. to 200° C., and the turning point during the second temperature rising was obtained and used as the glass transition temperature (Tg).

In addition, using the polymers of Example 1 to Example 28, Comparative Example 1, and Comparative Example 2 as a piezoelectric material, the piezoelectric film was produced by the following method, and the piezoelectric constant d₃₃ was measured. The results are shown in Table 1.

### (Production of Piezoelectric Film)

A piezoelectric material was dissolved in N,N-dimethylformamide as a solvent to prepare a 20 mass % polymer solution (coating solution). The obtained polymer solution was applied onto a PET film (product name, Lumirror (registered trademark), commercially available from Toray Industries, Inc.) as a substrate so that the thickness after drying was 50 μm to form a coating. Then, the coating formed on the PET film was dried on a hot plate at 120° C. for 6 hours, and the solvent in the coating was removed to obtain a piezoelectric material sheet.

The obtained piezoelectric material sheet was peeled off from the PET film, and an aluminum electrode was provided on one surface and the other surface of the piezoelectric material sheet by a vapor deposition method. Then, a high-voltage power supply device HARB-20R60 (commercially available from Matsusada Precision Inc.) and the electrode of the piezoelectric material sheet were electrically connected and held at 140° C. for 15 minutes while an electric field of 100 MV/m was applied, slow cooling was then performed to room temperature while a voltage was applied, and a polling treatment was performed to obtain a sheet-like piezoelectric film.

(Method of Measuring Piezoelectric Constant d₃₃)

A piezoelectric film was attached to a measurement device using a pin having a tip diameter of 1.5 mm as a sample fixing jig. As a measurement device for the piezoelectric constant d₃₃, Piezo Meter System PM200 (commercially available from PIEZOTEST) was used.

The measured value of the piezoelectric constant d₃₃ may be a positive value or a negative value depending on the front and back of the measured piezoelectric film. In this specification, the absolute value of the measured value is described as the value of the piezoelectric constant d₃₃.

As shown in Table 1, it was confirmed that the polymers of Example 1 to Example 28 had a higher glass transition temperature (Tg) and better heat resistance than the polymers of Comparative Example 1 and Comparative Example 2.

In addition, the piezoelectric film formed from the polymers of Example 1 to Example 28 as a piezoelectric material had a larger piezoelectric constant d₃₃ and better piezoelectric properties than the piezoelectric film formed from the polymer of Comparative Example 1 as a piezoelectric material and the piezoelectric film formed from the polymer of Comparative Example 2 as a piezoelectric material.

In particular, the piezoelectric film formed from the polymer of Example 2, Example 6, Example 7, Example 10, Example 11, Example 14, Example 15, Example 18, Example 19, Example 22, Example 26, or Example 27 in which the amount of the structural unit represented by Formula (2) was 30 to 60 mol % as a piezoelectric material had a larger piezoelectric constant d₃₃ and better piezoelectric property than other examples in which the structural units A to G represented by Formula (1) were the same.

1. A copolymer having a structural unit represented by the following General Formula (1) and a structural unit represented by the following Formula (2): 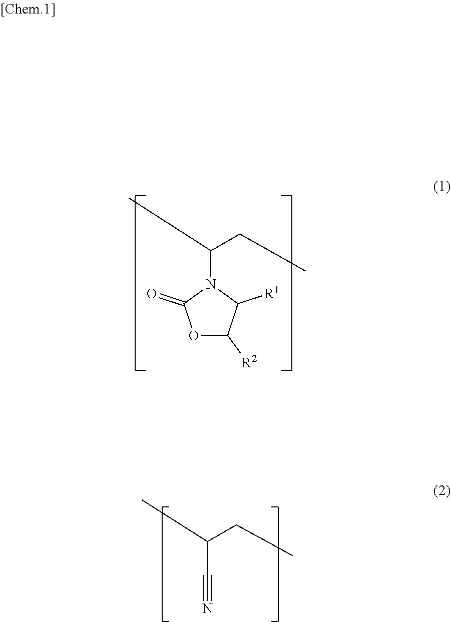
(in General Formula (1), R¹ and R² represent any one selected from the group consisting of a hydrogen atom, a methyl group, a dimethyl group, an ethyl group, an isopropyl group, an isobutyl group, a phenyl group, and a benzyl group, or R¹ and R² form a benzooxazolidinone framework together with an oxazolidinone ring).

2. The copolymer according to claim 1,
wherein, in General Formula (1), R¹ represents a hydrogen atom, R² represents one selected from the group consisting of a hydrogen atom, a methyl group, and a dimethyl group, or R¹ represents one selected from the group consisting of a methyl group, a dimethyl group, an ethyl group, and an isopropyl group, and R² represents a hydrogen atom.

3. The copolymer according to claim 1,
wherein, in General Formula (1), R¹ represents a hydrogen atom, and R² represents one selected from the group consisting of a hydrogen atom, a methyl group, and a dimethyl group.

4. The copolymer according to claim 1,
wherein, in General Formula (1), R¹ represents one selected from the group consisting of a methyl group, a dimethyl group, an ethyl group, and an isopropyl group, and R² represents a hydrogen atom.

5. The copolymer according to claim 1,
wherein the amount of the structural unit represented by Formula (2) is 10 to 80 mol %.

6. A piezoelectric material containing the copolymer according to claim 1.

7. A piezoelectric film containing the copolymer according to claim 1.

8. A piezoelectric element including the piezoelectric film according to claim 7 and an electrode disposed on a surface of the piezoelectric film.
